(19) United States
(12) Patent Application Publication
(10) Pub. No.: US 2005/0017282 A1
(43) Pub. Date: Jan. 27, 2005

(54) DRAM BURIED STRAP PROCESS WITH SILICON CARBIDE

(75) Inventors: David M. Dobuzinsky, New Windsor, NY (US); Jonathan E. Faltermeier, LaGrange, NY (US); Philip L. Flaitz, Newburgh, NY (US); Rajarao Jammy, Hopewell Junction, NY (US); Yuko Lisa Ninomiya, Danbury, CT (US); Ravikumar Ramachandran, Pleasantville, NY (US); Viraj Y. Sardesai, Poughkeepsie, NY (US); Yun Y. Wang, Poughquag, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/604,488

(22) Filed: Jul. 25, 2003

(51) Int. Cl. H01L 27/108

(52) U.S. Cl. 257/301

(57) ABSTRACT

In the process of forming a trench capacitor, the conductive strap connecting the center electrode of the capacitor with a circuit element in the substrate, such as the pass transistor of a DRAM cell, is separated from the crystalline substrate material by a barrier layer of silicon carbide formed during the process of etching the material within the trench, such as an oxide collar, using a reactive ion etch process with an etchant gas that contains carbon, such as C₄F₈.

### BACKGROUND OF INVENTION

The field of the invention is silicon integrated circuit formation processing.

In the construction of microelectronic devices, it is well known that there is a constant pressure for reduction of device size and/or increase of device capability at a given scale.

In the actual construction of reduced scale devices, attention must be paid to higher precision in configuring the materials from which the device components are formed. Attention must also be paid to the interaction of the various materials used in device construction during the device manufacture process, during device testing, and during device operation. In this regard, finer sized device components are more sensitive to adverse materials interactions since the amount of material forming the component is smaller. For example, an interaction that might have only affected the border area of a large component would affect an entire component of smaller scale (e.g., where the scale of the smaller component is the same size as the border area of the larger component). Thus, reduction in component scale forces consideration of materials interaction problems which could have been viewed as non-critical for larger scale components.

In the context of devices such as deep trench capacitors in semiconductor substrates, the various materials used to form the components of the capacitor such as the capacitor plates (electrodes), the dielectric barrier between electrodes, oxide collar structures to prevent or minimize parasitic effects, surface or buried straps to provide contact between the capacitor and the other circuitry of the device, etc. provide interfaces between dissimilar materials. For example, the electrode in the trench is typically a highly doped polycrystalline silicon (polysilicon) material, the buried or surface strap is typically an amorphous silicon, and the semiconductor substrate is a monocrystalline silicon. The successful functioning of the capacitor depends in part on the ability of these diverse materials to maintain their original or desirably modified character during manufacture/useful life of the device.

Unfortunately, the nature of these materials is such that unwanted interactions may occur unless otherwise prevented.

For example, a problem may be caused by the difference in crystallinity (or grain size) between the monocrystalline silicon substrate and the amorphous or polycrystalline silicon trench electrode material, especially where there is an intervening amorphous silicon material. In such configurations, the amorphous or polysilicon layer may template on the monocrystalline surface and recrystallize. Often, defects are created at the interface with the monocrystalline silicon during recrystallization which may propagate into the monocrystalline silicon. The occurrence of such defects is believed to adversely affect memory cell performance (the memory cell containing the capacitor). Specifically, the defects are believed to cause a lack of predictability of the charge retention time for the capacitor (so-called variable retention time). Such lack of predictability may limit the usefulness of the resulting device and/or the ability to maximize design performance.

Thus, there is a desire for improved capacitor structures which allow better control of materials interactions to enable construction of reliable reduced scale devices. It is also desired to meet these needs in an economical manner that minimizes or avoids compromise of other device or component properties.

In trench DRAM development, a buried strap is used for both-planar cell and vertical cell. It is understood that the buried strap has to be conductive and at the same time that it has to stop crystalline regrowth to prevent dislocation coming from buried strap.

U.S. Pat. Nos. 6,194,736 and 6,310,359 teach the formation of a very thin nitride barrier layer that suppresses recrystallization of amorphous or polycrystalline silicon while providing electrical continuity through quantum tunneling.

The '359 patent teaches that the presence of carbon in the barrier material is detrimental.

### SUMMARY OF INVENTION

The invention relates to the formation of a conductive barrier layer containing Silicon-carbon bonds between regions of differing degrees of crystallinity (or differing grain size).

In one aspect, the invention encompasses a method of forming a layer of carbon bonded to a silicon substrate as part of a plasma etching step, so that a separate deposition step is not required.

In another aspect, the invention encompasses a deep trench capacitor in a monocrystalline semiconductor substrate, the capacitor (i) comprising a buried plate in the substrate about an exterior portion of a trench in the substrate, (ii) a node dielectric about at least a lower interior portion of the trench, (iii) an electrode in the trench, and (iv) a conductive strap extending away from the trench electrode, at least a portion of the conductive strap being electrically connected to the trench electrode and the monocrystalline substrate, the capacitor further comprising (v) a Si—C barrier layer between the monocrystalline substrate and the trench electrode.

In another aspect, the invention encompasses structures having regions of similar composition (e.g., differing only by amount of dopant or by dopant composition, or having essentially no difference in composition), but differing degrees of crystallinity (or differing average grain size), separated by a silicon-carbon barrier layer. Preferably, a region on one side of the layer is amorphous or monocrystalline whereas a region on the other side of the layer is polycrystal line.

In another aspect, the invention encompasses methods of making trench capacitors containing barrier layers, the methods comprising reacting a silicon surface with a carbon compound to form a thin silicon-carbon compound layer.

These and other aspects of the invention are described in further detail below.

### BRIEF DESCRIPTION OF DRAWINGS

FIG. 1 is a schematic cross section of a structure having contiguous regions with a Si—C layer according to the invention.

FIG. 2 is a schematic plan view of a deep trench capacitor taken from trench top level with the buried strap exposed.

FIG. 3 is a schematic cross section of the deep trench capacitor structure of FIG. 2 at line A—A′.

FIGS. 4-7 illustrate steps in a first method using of making the invention.

FIGS. 8-9 illustrate steps in an alternative version of using the invention.

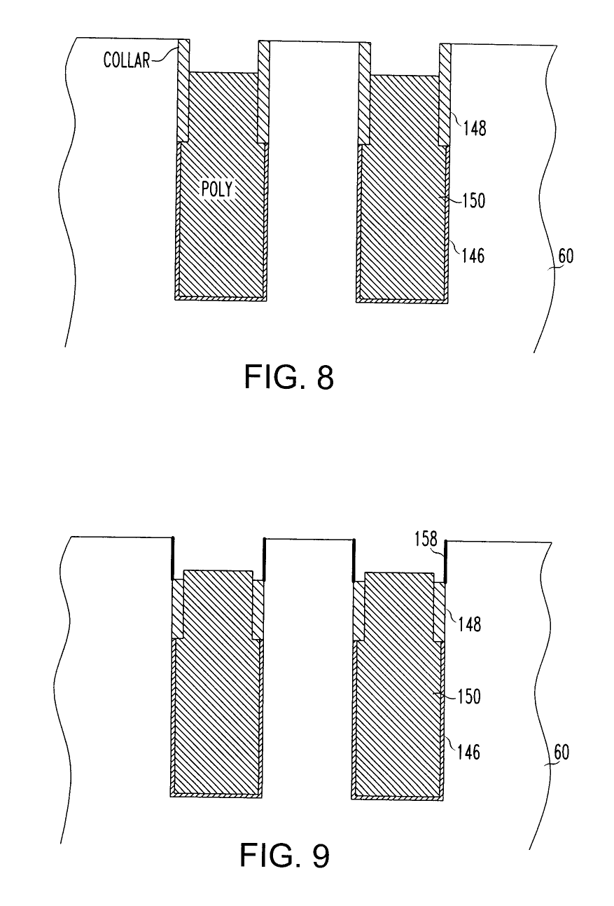

### DETAILED DESCRIPTION

In the formation of DRAM cells and other structures in silicon, it has been has been found that a carbon terminated silicon interface may suppress crystalline regrowth. The thickness for that interface has been found to be less than 0.8 nm.

Those skilled in the art are aware that silicon exposed to the atmosphere immediately forms an oxide terminated interface in which the “dangling bonds” at the silicon surface are linked to a layer of oxygen atoms; i.e. the surface layer of silicon has Si—O bonds. According to the invention, the Si—O bonds are replaced with Si—C bonds. It is not necessary for the benefits to be realized that the material on the silicon surface have the structure of silicon carbide. Accordingly, the layer of material formed on a silicon surface according to the invention will be referred to as a Si—C layer, which may or may not have any particular structure.

The invention provides Si—C barrier layers which are useful in control of stresses (e.g., associated with phase, lattice or thermal expansion mismatch, recrystallization or phase transformation) or other driving forces. The invention encompasses structures where such a barrier layer is formed at an interface between two regions which form part or all of a contiguous body (e.g. a portion of a semiconductor device). The barrier layer may provide a benefit in one of the regions immediately adjacent to the interface and/or may provide a benefit in a contiguous region not directly located at the interface.

Advantageously, the barrier layer may be formed at the end of a plasma enhanced oxide etch step that is already part of the process.

It is known in the art that a tough layer may be formed on trench sidewalls during a RIE process. This layer is considered to be a detriment, since it must be removed to provide proper electrical properties, but is difficult to remove. It is an advantageous feature of the invention to convent the detriment to an advantage.

The invention provides trench capacitor structures containing one or more Si—C barriers at locations within the structure (i) between the strap and the monocrystalline substrate, and/or (ii) between the strap and the trench electrode.

The barrier layers of the invention are very thin films of material containing silicon-carbon bonds which in the bulk form of silicon carbide would be considered dielectrics (i.e., electrical insulators). In very thin layers, however, these materials become electrically conductive. Advantageously, these thin layers have the ability to prevent or reduce transmission of forces associated with recrystallization from one side of the layer to the other. The silicon carbide used to make up the Si—C layers of the invention is an insulator in bulk.

It has been found that, when a plasma-enhanced oxide etch is performed with C₄F₈ as an etchant gas and parameters set conventionally to etch oxide without substantially attacking silicon, the use of an RF power level greater than or equal to 500 Watts produces a Si—C layer of less than 0.8 nm thickness that suppresses recrystallization as well as the nitride layers used in the references, while still providing adequate conductivity.

Normally, if there is less than 2 nm SiO₂ on top of the Si surface, the amorphous Si still can form epi-regrowth, because at high temperature, SiO₂ tend to form a small precipitates, and amorphous Si can crystallize on top of Si single crystal. The Si—C does not form a precipitate and at the same time it cannot be cleaned by normal organic cleaning solvents, because it is not an organic material. Therefore, even with an 0.8 nm thick layer, it can prevent the epi-regrowth of amorphous or polycrystalline Si on top of contaminated Si surface.

Advantageously, the formation of the Si—C layer at the end of the etching process is self-limiting, so that the thickness does not depend on time. Further, in contrast to the cited earlier work, the source of carbon is the etchant gas, so an additional step to form the barrier layer is not needed.

The barrier layers of the invention are preferably substantially uniform, however some variation in thickness may be permissible. Preferably, the layer thickness is kept in a range permitting the Si—C effect to take place for all points on the layer while performing the desired barrier function.

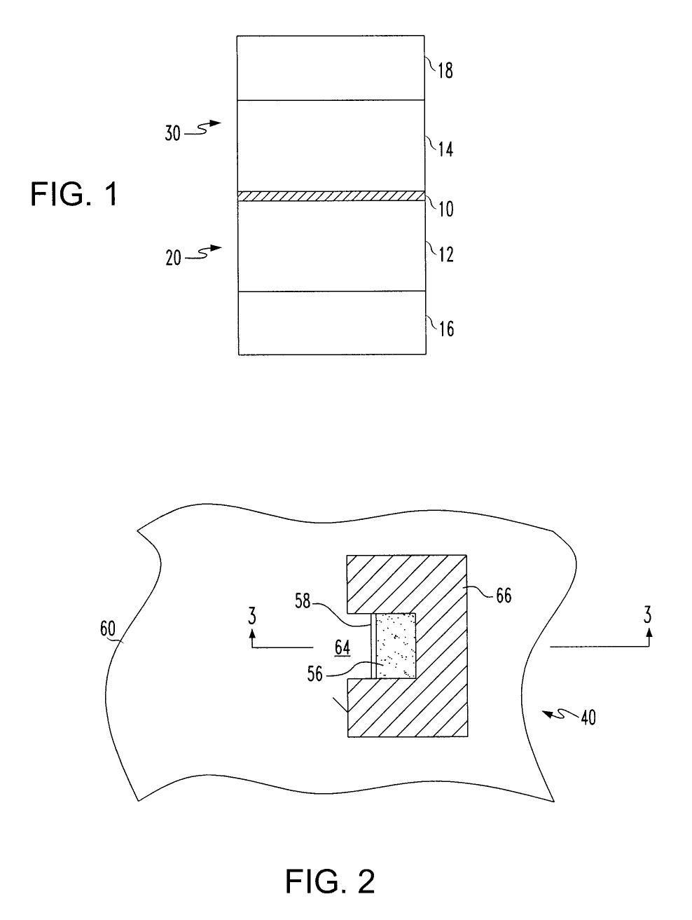

In the broadest sense, the invention encompasses structures wherein the Si—C layer intervenes between two regions having differing degrees of crystallinity or differing average grain size. Turning to FIG. 1, the Si—C layer 10, is preferably coextensive with at least one bordering region 12. While the layer 10 is illustrated in FIG. 1 as being coextensive with one region on each side, it should be understood that the invention includes other structures where the layer is coextensive with a plurality of regions on one side of the layer. Also, the layer 10 may be coextensive with regions on both sides, as shown in FIG. 1, or just with the region(s) on one side. The Si—C layer 10 is preferably continuous.

In FIG. 1, the relative thickness of Si—C layer 10 has been exaggerated for ease of illustration. Structure 1 contains silicon regions 12 and 16 on a first side 20 of Si—C layer 10 and regions 14 and 18 on the second side 30 of layer 10. Preferably, the structure is such that at least one region on first side 20 differs from at least one region on second side 30 either in (a) average grain size or (b) degree of crystallinity. The Si—C layers of the invention preferably act to control the effect of such differences between the regions on one side of the layer and the regions on the other side over the thermal history experienced by the structure.

Thus, the Si—C layers of the invention may be used to prevent or hinder forces associated with recrystallization of a region (e.g., region 12) from inducing changes in the crystallinity or crystal structure of regions 14 or 18 on the other side of layer 10. For example, if region 12 were a polycrystalline silicon and region 18 were a monocrystalline silicon, Si—C layer 10 could be used to prevent or inhibit stresses associated with recrystallization of region 12 (e.g., as might occur in thermal processing of the overall structure 1) from being transmitted to monocrystalline region 18 where those stresses could cause an undesired propagation of defects in the monocrystalline structure.

While the invention is not limited to any specific compositional makeup for the regions of the structure bordering or contiguous with the Si—C layer, preferably, at least one of the regions directly contacting the Si—C layer is a silicon material selected from the group consisting of monocrystalline silicon, amorphous silicon or polycrystalline silicon. The silicon material may be doped or undoped. A typical example structure might have a polycrystalline silicon on one side of the layer and an amorphous or monocrystalline silicon region on the other side.

The Si—C layers of the invention are especially useful in trench capacitor structures. Examples of typical trench capacitor structures are shown in U.S. Pat. Nos. 5,283,453; 5,395,786; 5,434,109; 5,489,544; 5,512,767; 5,576,566; 5,656,535; and 5,677,219, the disclosures of which are incorporated herein by reference. The trench capacitor structures of the invention are not limited to any specific configuration.

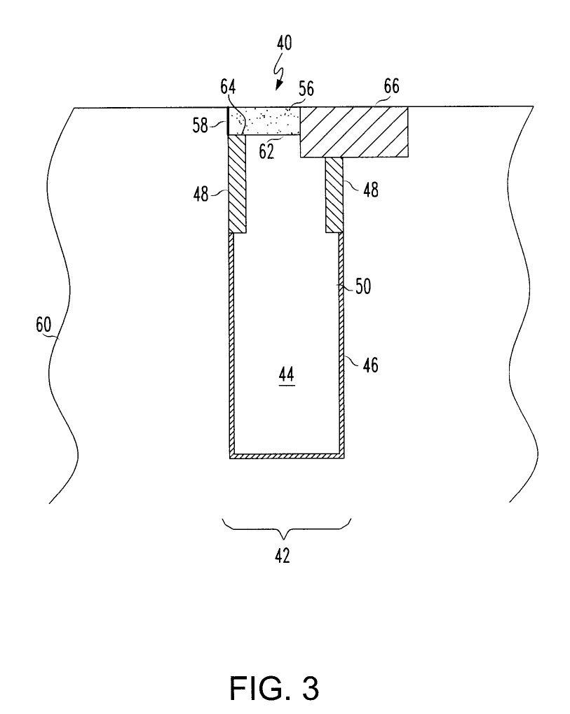

FIG. 2 shows a schematic plan view of a typical trench capacitor structure 40 taken at the top of the trench in a silicon substrate 60 with the buried strap 56 exposed to reveal interface 58 between substrate 60 and strap 56. Shallow trench isolation (STI) 66 surrounds the top area of capacitor 40 on three sides.

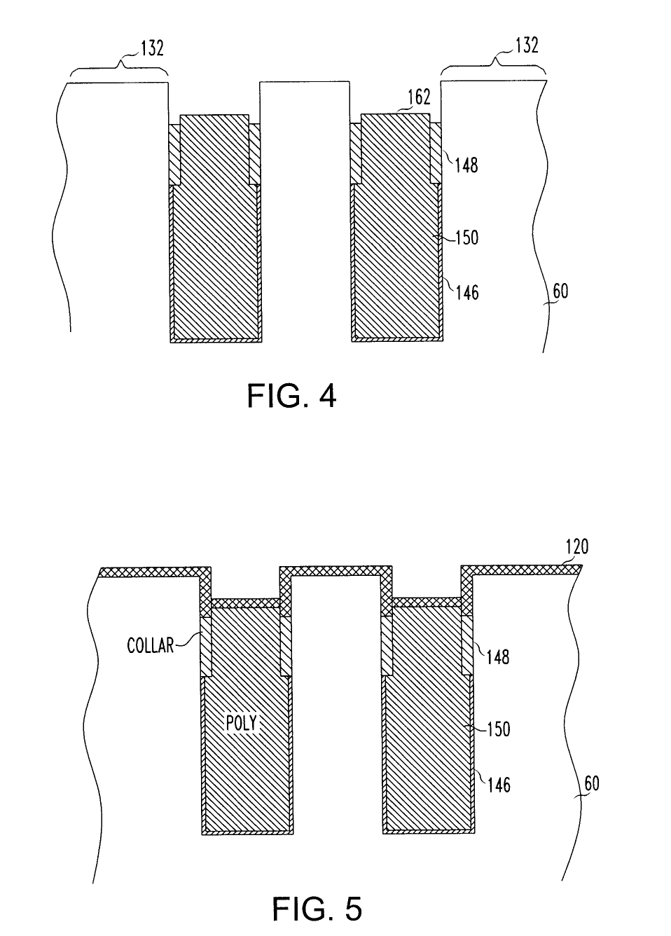

FIG. 3 shows a schematic side view of the trench capacitor of FIG. 2, taken through line 3-3. A buried plate electrode 42 is located about the exterior of a lower portion of the trench 44. A node dielectric 46 is present about the lower portion of the interior of trench 44. About the upper interior of trench 44 is an oxide collar 48. Trench 44 is filled with a conductive trench electrode material 50. A conductive strap 56 resides over and is electrically connected to trench electrode 50. Strap 56 thus provides electrical access to capacitor 40. While FIG. 3 shows a buried strap, the invention is not limited to any specific strap configuration. For example, the invention is equally applicable in the context of surface straps, lip straps (e.g., as disclosed in U.S. patent application Ser. No. 09/105,739, filed on Jun. 26, 1998, the disclosure of which is incorporated herein by reference) or other strap configurations.

The Si—C layers of the invention may be located at one or more locations within the trench capacitor structure as desired to prevent unwanted interactions. For example, a Si—C layer may be located at interface 58 between conductive strap 56 and substrate 60. Such a Si—C layer would be useful in preventing or inhibiting undesired transmission of recrystallization forces from strap 56 and/or trench electrode 50 to substrate 60. A Si—C layer may also be located at interface 62 between trench electrode 50 and strap 56. Such a Si—C layer would also be useful in preventing or inhibiting undesired transmission of recrystallization forces from trench electrode 50 to strap 56 and substrate 60. A side-effect of the use of the Si—C layers of the invention may be an inhibition of dopant diffusion from one side of the barrier layer to the other.

The invention encompasses trench capacitor structures where Si—C layers are located at one or more of the interfaces described above and/or at other locations within the capacitor structure as desired. The layer may also optionally be present at the interface 64 between collar oxide 48 and strap 56.

The composition and physical characteristics of the Si—C barriers used in the trench capacitors of the invention are preferably those described above with regard to general structures incorporating Si—C barriers. Advantageously, the Si—C layers can perform the desired barrier function without adversely affecting the electrical performance of the trench capacitor.

The invention is not limited to any specific material compositions for the various components of the trench capacitor. If desired, materials described in the art may be used. Thus, the trench electrode 50 would typically be made of a doped polycrystalline silicon or other suitably conductive material. Strap 56 would typically be made of amorphous silicon. Substrate 60 would typically be a monocrystalline semiconductor material (most typically silicon, lightly doped silicon or silicon having lightly doped bands). The buried plate 42 is typically a high dopant (e.g., arsenic) region within the substrate. The collar 48 and shallow trench isolation 66 are typically a silicon dioxide.

The use of alternative or modified materials may be enabled by the presence of the Si—C barriers of the invention. For example, trench electrode materials having very high dopant levels may be used (e.g., 5×10¹⁸-10²¹ dopant atoms per cm³). Alternative trench electrode materials (e.g., silicides, conductive metal nitrides, etc.) may also be used in place of conventional doped polysilicon. The composition of the strap may also be altered in the presence of suitable Si—C barrier layers.

While the Si—C layers of the invention are especially useful in trench capacitor structures, it should be understood that the layers may be used in other integrated circuit components where very thin conductive barrier layers are desired to prevent transmission of recrystallization forces.

The Si—C layers of the invention may be made by various methods. The choice of method may depend on the composition of the surface on which the layer is to be formed and/or the desired Si—C layer composition.

Where the surface on which the layer is to be formed has a high silicon content (e.g., a conventional (doped or undoped) polycrystalline, amorphous or monocrystalline silicon), the Si—C layer is preferably formed by reacting a portion of the silicon at the immediate surface with a carbon-containing compound in the atmosphere contacting the surface.

Those skilled in the art are aware of conventional choices for etchant gases for oxide etching that does not substantially attack silicon. Illustratively, a C₄F₈/CO/Ar gas in provided with a partial pressure of 10 mT to 90 mT in an Applied Materials 5000 etching tool and a power of 1000 to 2000 watts in the RF system. Preferably, the power has a value above 500 Watts for better formation of the Si—C.

The reaction is typically facilitated by heating the wafer to a temperature of about 20C to 80C. The reaction is typically self-limiting under these conditions, so that the layer thickness is not sensitive to time.

Advantageously, the substrate does not need precleaning by a chemical etch (e.g. HF solution and/or by a high temperature bake in a hydrogen atmosphere (or other appropriate reducing atmosphere) to remove some or all of any pre-existing oxide surface layer, since the oxide etching step takes care of removing oxide.

Trench capacitor structures containing the barrier layers of the invention may be formed by inserting one of the above layer formation techniques at an appropriate point(s) in the overall process of capacitor manufacturing process. The overall trench capacitor manufacturing process used may be any of those known in the art such as those described in the patents mentioned above. Alternatively, other variations on trench capacitor manufacturing processes may also be used (e.g., processes involving formation of collar oxides by the LOCOS technique).

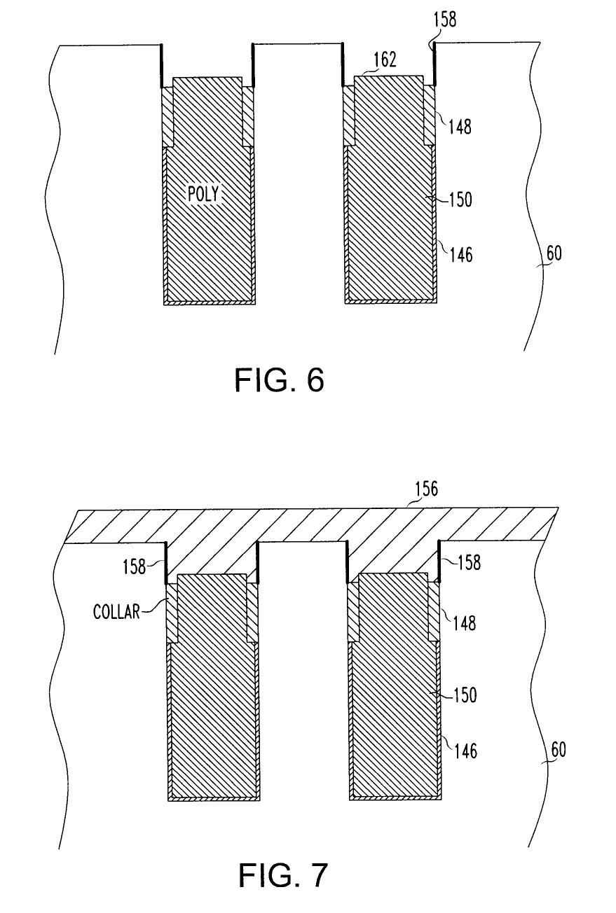

FIG. 4 illustrates a step in the use of the invention. A deep trench capacitor has been partially formed by etching a trench in a silicon substrate 60, depositing a nitride capacitor dielectric 146 on the interior of the trench, and filling the interior with a center electrode 150 of any convenient material, such as poly.

Intermediate conventional steps such as recessing poly 150, leaving a top surface 162, forming collar oxide 148 and filling the aperture have been omitted from the drawings.

The Figure shows the structure after a step of recessing the electrode 150 and collar oxide 148 in preparation for forming the buried strap that will connect the capacitor to the pass transistor. In the example illustrated, the pass transistor is a planar transistor that will be formed at the surface of substrate 60 at the location indicated by brackets 132, but the invention also applies to vertical transistor technology where the buried strap will be formed by diffusion into substrate 60 at the bottom of the collar oxide 148.

FIG. 5 shows the result of depositing a sacrificial oxide layer 120 that will serve as a vehicle to form the Si—C barrier layer. The thickness of the layer 120 is not critical, illustratively about 10 nm.

FIG. 6 shows the result of finishing the etch of the sacrificial oxide at a power level greater than or equal to 500 watts in an AME 5000 tool (or turning up the power at the end of the etch). A barrier layer 158 has been formed on the vertical walls of the trench and also on the horizontal surface 162. If the layer on the horizontal surface is not wanted, it may be removed by a directional etch.

FIG. 7 shows the structure after the deposition of poly 156 that will form the buried strap. Conventional steps of recessing poly 156 and forming a cap oxide (if desired) are omitted, as are the conventional steps of forming the pass transistors and the back end of the process that forms the completed integrated circuit.

One method of forming a deep trench capacitor in a monocrystalline semiconductor substrate, with Si—C layers at both the interface of the strap and the substrate and the interface of the strap and the trench electrode, comprises: (a) providing a monocrystalline semiconductor substrate having (i) a buried plate about an exterior portion of a trench in the substrate, (ii) a node dielectric about at least a lower interior portion of the trench, and (iii) an electrode in the trench, (b) removing an upper portion of the electrode to provide space for a conductive strap, thereby exposing electrode and substrate surface, (c) reacting in the presence of a plasma, the exposed surface of the electrode and the substrate about the space with a carbon compound to form a Si—C layer on the electrode and substrate surfaces, and (d) filling the space over the Si—C layer with a conductive strap material.

Preferably, the reaction step is part of a reactive ion etch (RIE) that removes oxide using the carbon compound as etchant. Also preferably, a collar oxide is provided about the upper interior portion of the trench in step (a). Shallow trench isolation would typically be formed after filling step (d) by etching to define a space for the isolation and filling that space with the desired shallow trench isolation material.

Where a Si—C layer is desired only at the interface of the strap and the trench electrode, a mask layer may be directionally deposited (e.g., by HDP deposition) over the layer formed in step (c) whereby the mask is thicker over the SiC layer on the trench electrode surface. This mask may be removed from the Si—C layer on the substrate surface by isotropic etching (with partial reduction in thickness of the mask over the Si—C layer on the trench electrode surface. The Si—C layer on the substrate surface is then preferably removed by a selective isotropic etch to re-expose the substrate surface first exposed in step (b). The remaining mask over the Si—C layer on the trench electrode surface may then by removed by a further selective etch process. The process could then continue with filling step (d).

Alternatively, a deep trench capacitor according to the invention with a Si—C layer at the interface of the strap and the trench electrode may be formed by: (a) providing a monocrystalline semiconductor substrate having (i) a buried plate in an exterior portion of trench in the substrate, (ii) a node dielectric about at least a lower interior portion of the trench, and (iii) an electrode in the trench, (b) removing an upper portion of the electrode to provide space for a conductive strap, thereby exposing electrode and substrate surface, (c) depositing a thin dielectric material layer (collar oxide) on the substrate surface, (d) isotropically etching the thin dielectric material layer to remove any dielectric material deposited on the exposed substrate surface using an etchant containing carbon, thereby leaving a Si—C layer on the substrate surface, and (e) filling the space formed in step (b) with a conductive strap material.

Shallow trench isolation would typically be formed after filling step (e) by etching to define a space for the isolation and filling that space with the desired shallow trench isolation material.

Where a surface strap is used, the above processes would be modified by eliminating steps for forming space for the buried strap. Where a trench capacitor formation process does not naturally provide the surface where a barrier is desired, such a process can be modified by adding appropriate etch back, layer formation and fill steps, as in the case of a vertical transistor DRAM cell, the etch and fill steps being selected from those known in the art for the specific materials involved.

The preferred embodiment of the invention employs an etching tool using an etchant gas containing carbon on an oxide layer and performing a reactive ion etching process enhanced by a plasma. Those skilled in the art will appreciate that other tools or processes may be used to provide the layer of Si—C bonds.

While the invention has been described in terms of a single preferred embodiment, those skilled in the art will recognize that the invention can be practiced in various versions within the spirit and scope of the following claims.

1. A deep trench capacitor in a monocrystalline semiconductor substrate, said capacitor comprising: (i) a buried plate in said substrate about an exterior portion of a trench in said substrate, (ii) a node dielectric about at least a lower interior portion of said trench, (iii) a trench electrode in said trench, and (iv) a conductive strap extending away from said trench electrode, the conductive strap being electrically connected to the trench electrode and the monocrystalline substrate, said capacitor further comprising (v) a Si—C barrier layer between said monocrystalline substrate and said trench electrode.

2. The capacitor of claim 1, further comprising an oxide collar about an upper interior region of said trench and disposed below said conductive strap.

3. The capacitor of claim 1, wherein said Si—C barrier layer is located at an interface between said trench electrode and said conductive strap.

4. The capacitor of claim 1, wherein said Si—C barrier layer is located at an interface between said conductive strap and said monocrystalline substrate.

5. The capacitor of claim 4, wherein the interface is located below a vertical transistor.

6. The capacitor of claim 1, wherein said Si—C barrier layer has a thickness of about 10 nm.

7. The capacitor of claim 1, wherein said conductive strap is a buried strap.

8. The capacitor of claim 1, wherein said conductive strap comprises amorphous silicon.

9. The capacitor of claim 1, wherein said trench electrode comprises doped polycrystalline silicon.

10. The capacitor of claim 3, further comprising an additional Si—C barrier layer located at an interface between said conductive strap and said monocrystalline substrate.

11. A method of forming a deep trench capacitor in a monocrystalline semiconductor substrate, said method comprising:
(a) providing a monocrystalline semiconductor substrate having (i) a buried plate about an exterior portion of trench in said substrate, (ii) a node dielectric about at least a lower interior portion of said trench, and (iii) a trench electrode in said trench;
(b) removing an upper portion of said trench electrode to provide space for a conductive strap, thereby exposing a trench electrode surface and a vertical substrate surface;
(c) reacting, in the presence of an electric field, said exposed surface of the electrode and the substrate about said space with a compound containing carbon to form a Si—C barrier layer on at least said substrate surface; and
(d) filling said space over said electrode layer with a conductive strap material.

12. A method according to claim 11, wherein said step of removing an upper portion is performed with a reactive ion etch on oxide and said compound containing carbon is the etchant gas.

13. A method according to claim 12, wherein a power level of RF power is above a threshold value.

14. A method according to claim 13, wherein said power level is maintained at the end of an oxide removal etching process.

15. The method of claim 11, further comprising removing said Si—C layer from said trench electrode surface before step (d).

16. The method of claim 11, wherein step (c) is performed at about 20 to 80 degrees Centigrade.

17. The method of claim 11 wherein step (a) further comprises providing an oxide collar about an upper interior region of said trench, and step (b) further comprises removing a portion of said oxide collar and thereby exposes a vertical surface of said substrate.

18. A method according to claim 18, wherein said step of removing an upper portion is performed with a reactive ion etch on oxide and said compound containing carbon is the etchant gas.

19. A method according to claim 18, wherein a power level of RF power is above a threshold value.
